(19) United States
(12) Patent Application Publication
(10) Pub. No.: US 2025/0301630 A1
(43) Pub. Date: Sep. 25, 2025

(54) SEMICONDUCTOR DEVICE AND METHOD FOR MANUFACTURING SEMICONDUCTOR DEVICE

(71) Applicant: Kioxia Corporation, Tokyo (JP)

(72) Inventors: Kenichi HAGA, Yokkaichi Mie (JP); Akinori KAMIYAMA, Yokkaichi Mie (JP); Kohei KAWAGUCHI, Yokkaichi Mie (JP)

(21) Appl. No.: 19/066,075

(22) Filed: Feb. 27, 2025

(30) Foreign Application Priority Data
Mar. 21, 2024 (JP) 2024-044495

(51) Int. Cl. H10B 12/00

(52) U.S. Cl. CPC H10B 12/33; H10B 12/05

(57) ABSTRACT

A semiconductor device includes an oxide semiconductor layer extending in a first direction and including a first end portion, a second end portion, and an intermediate portion between the first and second end portions, a first electrode in contact with the first end portion of the oxide semiconductor layer, a second electrode in contact with the second end portion of the oxide semiconductor layer, and a conductive layer surrounding the intermediate portion of the oxide semiconductor layer via an insulation film. At least one of a cavity or an insulation layer is disposed in the intermediate portion of the oxide semiconductor layer.

CROSS-REFERENCE TO RELATED APPLICATION(S)

This application is based upon and claims the benefit of priority from Japanese Patent Application No. 2024-044495, filed Mar. 21, 2024, the entire contents of which are incorporated herein by reference.

### FIELD

Embodiments described herein relate generally to a semiconductor device and a method for manufacturing a semiconductor device.

### BACKGROUND

In some semiconductor devices, an oxide semiconductor layer is used as a channel.

### BRIEF DESCRIPTION OF THE DRAWINGS

FIG. 1 is a circuit diagram illustrating a circuit configuration of a memory cell array according to an embodiment.

FIG. 2 is a cross-sectional view illustrating a cross-sectional structure of a semiconductor memory device according to an embodiment.

FIG. 3 is a cross-sectional view illustrating a cross-sectional structure of a semiconductor device according to an embodiment.

FIG. 4 is a cross-sectional view illustrating a part of a manufacturing process of the semiconductor device.

FIG. 5 is a cross-sectional view illustrating a part of the manufacturing process of the semiconductor device.

FIG. 6 is a cross-sectional view illustrating a part of the manufacturing process of the semiconductor device.

FIG. 7 is a cross-sectional view illustrating a part of the manufacturing process of the semiconductor device.

FIG. 8 is a cross-sectional view illustrating a part of the manufacturing process of the semiconductor device.

FIG. 9 is a cross-sectional view illustrating a part of the manufacturing process of the semiconductor device.

FIG. 10 is a cross-sectional view illustrating a part of the manufacturing process of the semiconductor device.

FIG. 11 is a cross-sectional view illustrating a cross-sectional structure of a semiconductor device according to a comparative example.

FIG. 12 is a cross-sectional view illustrating a cross-sectional structure of a semiconductor device according to a first modification example.

FIG. 13 is a cross-sectional view illustrating a cross-sectional structure of a semiconductor device according to a second modification example.

FIG. 14 is a cross-sectional view illustrating a cross-sectional structure of a semiconductor device according to a third modification example.

FIG. 15 is a cross-sectional view illustrating a cross-sectional structure of a semiconductor device according to a fourth modification example.

FIG. 16 is a cross-sectional view illustrating a cross-sectional structure of a semiconductor device according to a fifth modification example.

FIG. 17 is a cross-sectional view illustrating a cross-sectional structure of a semiconductor device according to a sixth modification example.

FIG. 18 is a cross-sectional view illustrating a cross-sectional structure of the semiconductor device according to the sixth modification example.

FIG. 19 is a cross-sectional view illustrating a cross-sectional structure of a semiconductor device according to a seventh modification example.

FIG. 20 is a cross-sectional view illustrating a cross-sectional structure of the semiconductor device according to the seventh modification example.

FIG. 21 is a cross-sectional view illustrating a cross-sectional structure of a semiconductor device according to an eighth modification example.

FIG. 22 is a cross-sectional view illustrating a cross-sectional structure of the semiconductor device according to the eighth modification example.

FIG. 23 is a cross-sectional view illustrating a cross-sectional structure of the semiconductor device according to the eighth modification example.

### DETAILED DESCRIPTION

Embodiments provide a semiconductor device and a method for manufacturing a semiconductor device capable of achieving both an ON current and a threshold voltage in a preferable manner.

In general, according to one embodiment, a semiconductor device comprises an oxide semiconductor layer extending in a first direction and including a first end portion, a second end portion, and an intermediate portion between the first and second end portions, a first electrode in contact with the first end portion of the oxide semiconductor layer, a second electrode in contact with the second end portion of the oxide semiconductor layer, and a conductive layer surrounding the intermediate portion of the oxide semiconductor layer via an insulation film. At least one of a cavity or an insulation layer is disposed in the intermediate portion of the oxide semiconductor layer.

Embodiments will be described below with reference to the accompanying drawings. In order to facilitate the understanding of the descriptions, the same components in each drawing are denoted by the same reference sign as much as possible, and duplicate descriptions are omitted.

### 1 Embodiments

In each drawing, an X-axis, a Y-axis, and a Z-axis may be indicated. The X-axis, the Y-axis, and the Z-axis form a right-handed three-dimensional orthogonal coordinate system. In the following description, a direction of the arrow of the X-axis may be referred to as a+X direction, a direction opposite to the arrow may be referred to as a −X direction, and the same applies to other axes. The+Z direction and the −Z direction may also be referred to as “above” and “below”, respectively. Planes orthogonal to the X-axis, the Y-axis, and the Z-axis may be referred to as a YZ plane, a ZX plane, and a XY plane, respectively. A direction of the Z-axis may be referred to as an “up-down direction”. The terms “above”, “below” and “up-down direction” are merely terms indicating a relative positional relationship in the drawings, and are not terms defining an orientation with reference to the vertical direction.

In the present specification, “connection” includes not only physical connection but also electrical connection, and includes not only direct connection but also indirect connection unless otherwise specified.

In the present specification, “formed above” includes not only a case where an element is formed above another element in contact with the another element, but also a case where an element is formed above another element with still another element interposed between the element and the another element, unless otherwise specified. The same applies to “formed below” and the like.

### 1.1 Schematic Configuration of Semiconductor Device

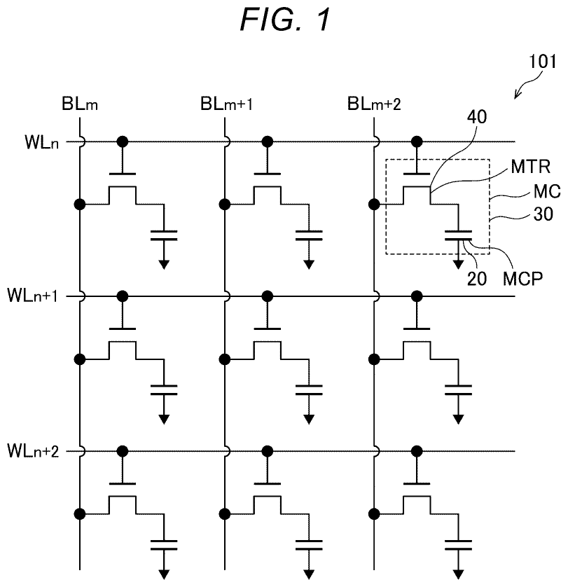

FIG. 1 is a circuit diagram illustrating a circuit configuration of a semiconductor memory device 101 according to an embodiment. The semiconductor memory device 101 illustrated in FIG. 1 is an oxide semiconductor random access memory (OS-RAM) and includes a memory cell array. As illustrated in FIG. 1, the memory cell array includes a plurality of memory cells MC, a plurality of word lines WL, and a plurality of bit lines BL.

As examples of the word lines WL, a word line WLn, a word line WLn+1, and a word line WLn+2 are illustrated in FIG. 1. “n” is a positive integer. As examples of the bit lines BL, a bit line BLm, a bit line BLm+1, and a bit line BLm+2 are illustrated in FIG. 1. “m” is a positive integer. It should be noted that the number of the plurality of memory cells MC is not limited to the number illustrated in FIG. 1.

The plurality of memory cells MC are arranged, for example, in a matrix to form a memory cell array. The memory cell MC includes a memory transistor MTR and a memory capacitor MCP. The memory transistor MTR is a field-effect transistor (FET).

A series of memory cells MC provided along a row direction is connected to a word line WL corresponding to the row to which the series of memory cells MC belongs. For example, the memory cells MC belonging to the n-th row is connected to the word line WLn. A series of memory cells MC provided along a column direction is connected to a bit line BL corresponding to the column to which the series of memory cells MC belongs. For example, the memory cells MC belonging to the (m+2)-th row is connected to the bit line BLm+2.

More specifically, the gate of the memory transistor MTR in a memory cell MC is connected to a word line WL corresponding to the row to which the subjected memory cell MC belongs. One of the source and the drain of the memory transistor MTR is connected to a bit line BL corresponding to the column to which the subjected memory cell MC belongs.

One electrode of a memory capacitor MCP in the memory cell MC is connected to the other of the source and the drain of the memory transistor MTR in the subjected memory cell MC. The other electrode of the memory cell MC is connected to a power line (not illustrated) supplying a predetermined potential.

The memory cell MC is capable of storing data as a result of accumulation of electric charges in the memory capacitor MCP by a current flowing through the corresponding bit line BL by switching of the memory transistor MTR based on the potential of the corresponding word line WL.

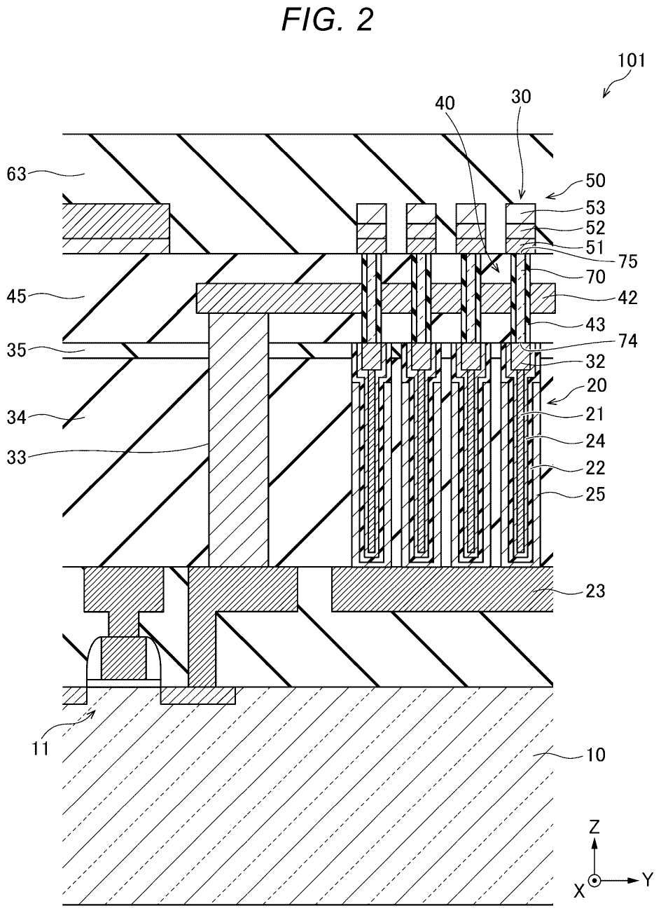

FIG. 2 is a cross-sectional view illustrating a cross-sectional structure of the semiconductor memory device 101 parallel to the ZX plane. As illustrated in FIG. 2, the semiconductor memory device 101 includes a semiconductor substrate 10, a circuit 11, a capacitor 20, a semiconductor device 30, a conductor 33, and insulation layers 34, 35, 45, and 63.

The capacitor 20 includes a conductor 21, an insulation film 22, a conductor 23, a capacitor electrode 24, and a capacitor electrode 25.

The semiconductor device 30 includes a field-effect transistor 40, an upper electrode 50, and a lower electrode 32. The lower electrode 32 is provided below the field-effect transistor 40. The upper electrode 50 is provided above the field-effect transistor 40. In the semiconductor device 30, the lower electrode 32 functions as one of the source electrode and the drain electrode of the field-effect transistor 40, and the upper electrode 50 functions as the other of the source electrode and the drain electrode.

The field-effect transistor 40 includes an oxide semiconductor layer 70, a conductive layer 42, and a gate insulation film 43.

The oxide semiconductor layer 70 is formed in the insulation layer 45. The oxide semiconductor layer 70 includes a lower end 74 and an upper end 75. The oxide semiconductor layer 70 has a columnar body extending in the +Z direction from the lower end 74 to the upper end 75. The oxide semiconductor layer 70 forms a channel of the field-effect transistor 40. The oxide semiconductor layer 70 has an amorphous structure. The oxide semiconductor layer 70 is a semiconductor in which an oxygen deficiency serves as a donor, and contains indium (In), zinc (Zn), and gallium (GA) as metal elements. More specifically, the oxide semiconductor layer 70 is an oxide of indium, gallium, and zinc, that is, IGZO (InGaZnO). It should be noted that the oxide semiconductor layer 70 may be an oxide semiconductor of another type.

The conductive layer 42 serves as a gate electrode of the field-effect transistor 40. The conductive layer 42 surrounds the oxide semiconductor layer 70 via the gate insulation film 43 between the lower end 74 and the upper end 75 of the oxide semiconductor layer 70. The conductive layer 42 contains, for example, tungsten (W).

The gate insulation film 43 includes, for example, a silicon nitride film (Si3N4) containing silicon and nitrogen.

The upper electrode 50 is formed in the +Z direction with respect to the oxide semiconductor layer 70. The upper electrode 50 is in contact with the upper end 75 of the oxide semiconductor layer 70. The upper electrode 50 includes a metal oxide layer 51, a barrier metal layer 52, and a metal film 53.

The metal film 53 contains tungsten. The metal oxide layer 51 is formed between the metal film 53 and the upper end 75 of the oxide semiconductor layer 70. The metal oxide layer 51 contains metal oxide containing metal elements such as indium and tin, for example. In one embodiment, the metal oxide layer 51 is made of indium-tin-oxide (ITO).

The barrier metal layer 52 contains titanium and nitrogen. The barrier metal layer 52 is formed between the metal oxide layer 51 and the metal film 53. In the present embodiment, the barrier metal layer 52 is made of, for example, titanium nitride (TiN).

The lower electrode 32 is in contact with the lower end 74 of the oxide semiconductor layer 70. The lower electrode 32 is made of, for example, an ITO layer containing metal oxide such as indium-tin-oxide (ITO). It should be noted that the lower electrode 32 is not limited to being made of the ITO layer, but may contain at least one of indium, tin, zinc, cadmium, gold, silver, platinum, lead, copper, nickel, tungsten, or iron.

The circuit 11 forms a peripheral circuit such as a decoder, a sense amplifier connected to the bit line BL, and a resistor including an SRAM. The decoder selects a predetermined memory cell MC out of the plurality of memory cells MC of the semiconductor memory device 101. The circuit 11 may include a CMOS circuit including a P-channel field-effect transistor (Pch-FET) and an N-channel field-effect transistor (Nch-FET) formed by a CMOS process.

The field-effect transistors in the circuit 11 can be formed using the semiconductor substrate 10 such as a single crystal silicon substrate. Each of the Pch-FET and the Nch-FET is a field-effect transistor including a channel region, a source region, and a drain region on the semiconductor substrate 10. More specifically, each of the Pch-FET and the Nch-FET is a so-called horizontal field-effect transistor including a channel that allow carriers to flow in the direction of the X-axis or the direction of the Y-axis substantially parallel to a surface of the semiconductor substrate 10 in a region close to the surface of the semiconductor substrate 10. It should be noted that the semiconductor substrate 10 may be of a conductive type of P-type or N-type. For convenience, FIG. 2 illustrates an example of the field-effect transistor of the circuit 11.

The capacitor 20 is a memory capacitor MCP provided in the memory cell MC illustrated in FIG. 1. FIG. 2 illustrates four capacitors 20, but the number of the capacitors 20 is not limited to four.

In the present embodiment, the capacitor 20 is provided above the semiconductor substrate 10. The capacitor electrode 24 of the capacitor 20 is connected to the conductor 21 and the lower electrode 32. The capacitor electrode 25 is opposed to the capacitor electrode 24. The insulation film 22 is provided between the capacitor electrode 24 and the capacitor electrode 25.

The capacitor 20 is a three-dimensional capacitor such as a pillar-type capacitor. As the capacitor of the present embodiment, another type of capacitor may be employed.

The conductor 21 is in contact with the lower end surface of the lower electrode 32 and extends downward from the subjected end surface. The capacitor electrode 24 is formed such that the capacitor electrode 24 covers the lower electrode 32 and the conductor 21. The insulation film 22 is formed such that the insulation film 22 covers the capacitor electrode 24. The capacitor electrode 25 is proved such that the capacitor electrode 25 surrounds a lower part of the insulation film 22. The lower end of the capacitor electrode 25 is in contact with the upper end surface of the conductor 23.

The conductor 21 may contain a material such as amorphous silicon. The insulation film 22 may contain a material such as hafnium oxide. The conductor 23 and the capacitor electrodes 24 and 25 may contain materials such as tungsten and titanium nitride.

The conductor 33 includes wiring that electrically connects the circuit 11 and the semiconductor device 30. The conductor 33 includes a via line extending in the direction of the Z-axis as illustrated in FIG. 2. The via line connects the word line WL and the circuit 11 provided on the semiconductor substrate 10. The conductor 33 contains, for example, copper.

The insulation layer 34 is provided between the plurality of capacitors 20. The insulation layer 34 is, for example, a silicon oxide film containing silicon and oxygen.

The insulation layer 35 is provided above the insulation layer 34. The insulation layer 35 is, for example, a silicon nitride film containing silicon and nitrogen.

The semiconductor device 30 is provided above the capacitor 20. The field-effect transistor 40 in the semiconductor device 30 corresponds to the memory transistor MTR of the memory cell MC illustrated in FIG. 1.

In the semiconductor device 30 illustrated in FIG. 2, the field-effect transistor 40 is provided above the lower electrode 32. More specifically, the oxide semiconductor layer 70 of the field-effect transistor 40 is located above the lower electrode 32, that is, located in a direction separating from the semiconductor substrate 10. The upper electrode 50 is located above the oxide semiconductor layer 70, that is, located in a direction separating from the semiconductor substrate 10.

With the structure described above, the field-effect transistor 40 is formed as a so-called vertical transistor including a channel that extends in the Z-axis direction (i.e., the up-down direction) substantially perpendicular to a surface of the semiconductor substrate 10.

### 1.2 Structure of Semiconductor Device

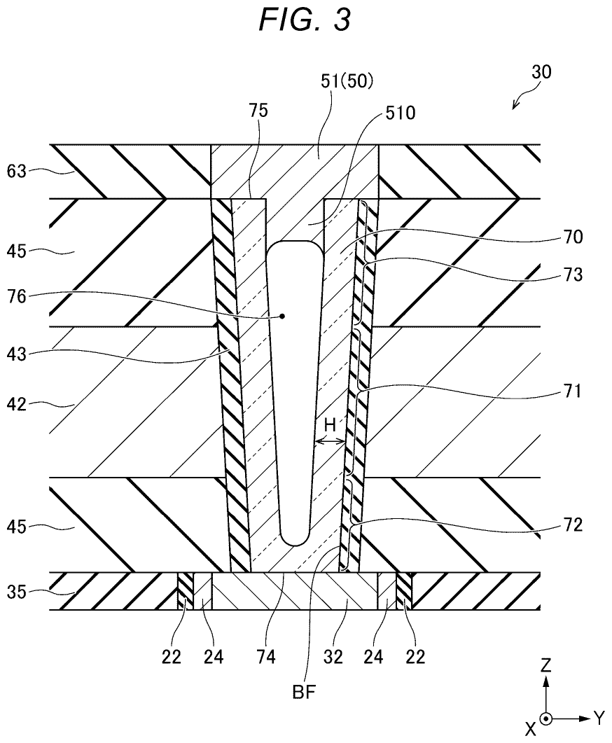

The structure of the semiconductor device 30 will be described. FIG. 3 is a cross-sectional view illustrating a cross-sectional structure of the semiconductor device 30.

As illustrated in FIG. 3, the oxide semiconductor layer 70 is tapered to become narrower from the upper end 75 toward the lower end 74, that is, toward the −Z direction. The gate insulation film 43 is provided to surround the oxide semiconductor layer 70, and thus is tapered similarly to the oxide semiconductor layer 70. The conductive layer 42 is provided to surround a predetermined portion 71 located substantially at the center of the oxide semiconductor layer 70 via the gate insulation film 43. In the following description, the predetermined portion 71 of the oxide semiconductor layer 70 is referred to as an “intermediate portion 71”. In the oxide semiconductor layer 70, a portion located in the-Z direction with respect to the intermediate portion 71 is referred to as a “lower portion 72”. In the oxide semiconductor layer 70, a portion located in the +Z direction with respect to the intermediate portion 71 is referred to as an “upper portion 73”.

A cavity 76 is formed in the oxide semiconductor layer 70. Thus, the oxide semiconductor layer 70 has a hollow structure. The cavity 76 extends in the Z-axis direction from the inside of substantially the center of the upper portion 73 of the oxide semiconductor layer 70 to the inside of substantially the center of the lower portion 72 through the inside of the intermediate portion 71. The cavity 76 is also tapered to become narrower toward the −Z direction similarly to the oxide semiconductor layer 70 and the gate insulation film 43.

The metal oxide layer 51 is formed with a projecting portion 510 extending in the −Z direction from the upper end 75 of the oxide semiconductor layer 70 to the inside of the oxide semiconductor layer 70. The lower end of the projecting portion 510 reaches the cavity 76 in the oxide semiconductor layer 70.

### 1.3 Method for Manufacturing Semiconductor Device

A method for manufacturing the semiconductor device 30 will be described.

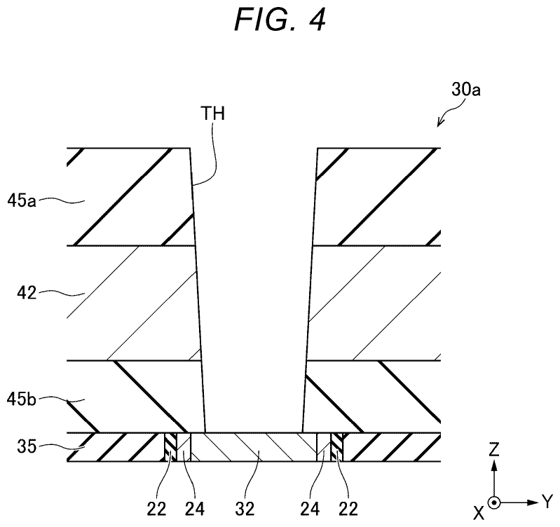

In manufacturing the semiconductor device 30, a formed body 30a as illustrated in FIG. 4 is first made. In the formed body 30a, an insulation layer 45b, the conductive layer 42, and an insulation layer 45a are formed in this order above the insulation layer 35. The insulation layer 45b, the conductive layer 42, and the insulation layer 45a extend substantially in parallel with the XY plane. The insulation layer 45a and the insulation layer 45b form the insulation layer 45 illustrated in FIG. 3. The formed body 30a is formed with a transistor hole TH penetrating the insulation layer 45a, the conductive layer 42, and the insulation layer 45b. The transistor hole TH extends substantially in parallel with the Z-axis. The upper surface of the lower electrode 32 is exposed at the bottom portion of the transistor hole TH.

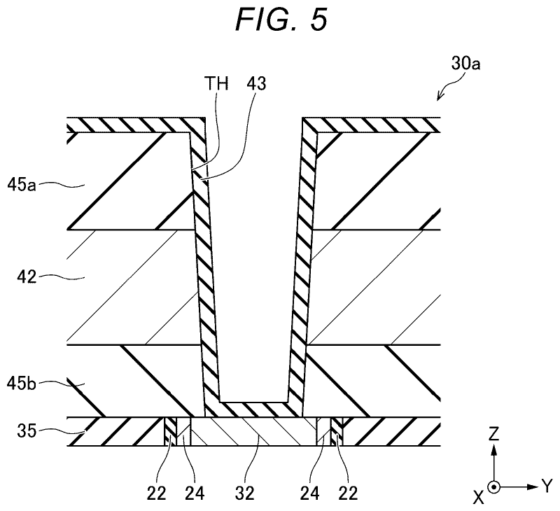

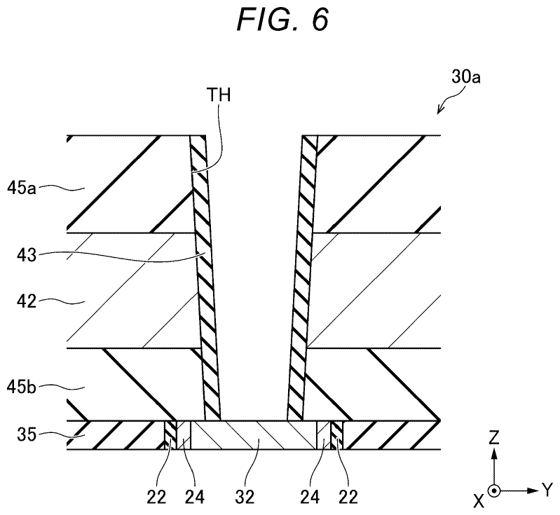

After the insulation film 43 is formed on the upper surface of the formed body 30a as illustrated in FIG. 5, a part of the insulation film 43 is removed by reactive ion etching. Accordingly, the upper side of the formed body 30a is etched back such that the insulation layer 45a is exposed, and the lower electrode 32 is exposed at the bottom portion of the transistor hole TH, as illustrated in FIG. 6.

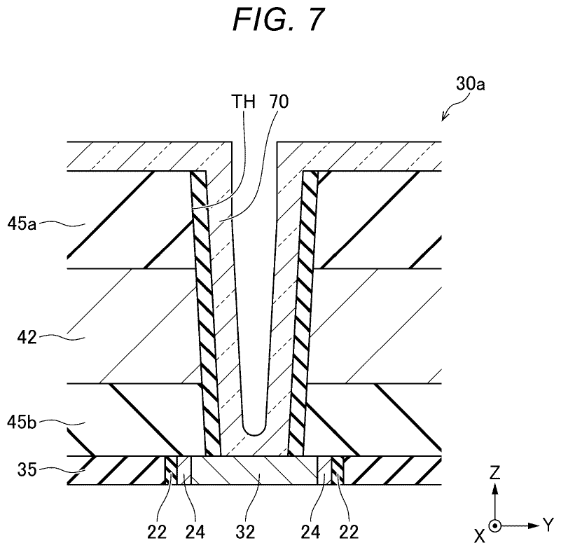

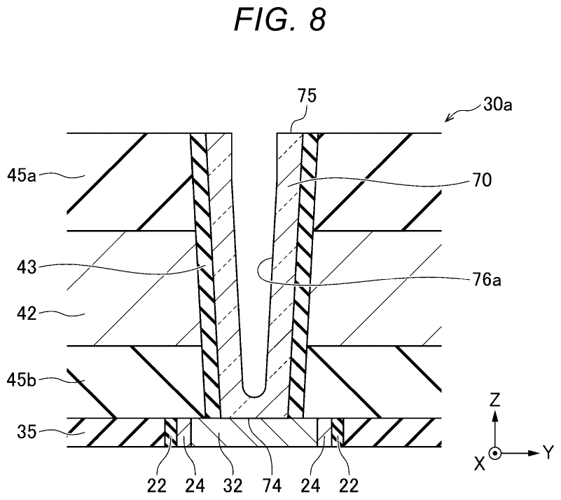

Next, the oxide semiconductor layer 70 is formed on the upper surface of the formed body 30a by an atomic layer deposition (ALD) method as illustrated in FIG. 7, and then chemical mechanical polishing is performed on the upper side of the formed body 30a. As a result, the formed body 30a illustrated in FIG. 8 is formed. The formed body 30a illustrated in FIG. 8 is formed with a long hole 76a extending in the Z-axis direction through the central portion of the oxide semiconductor layer 70. The long hole 76a opens at the upper end 75 of the oxide semiconductor layer 70.

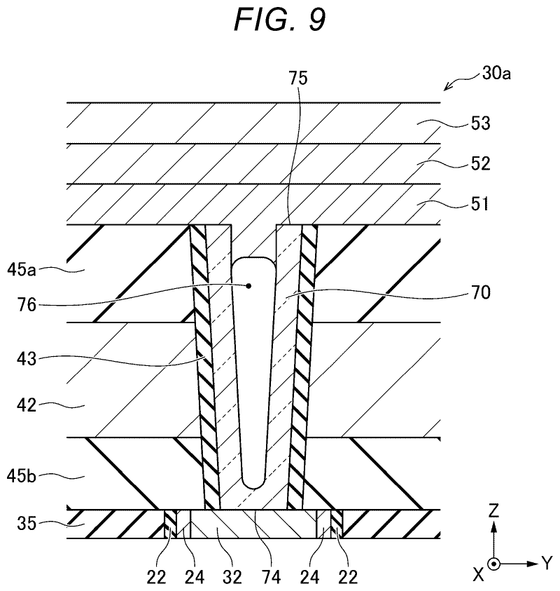

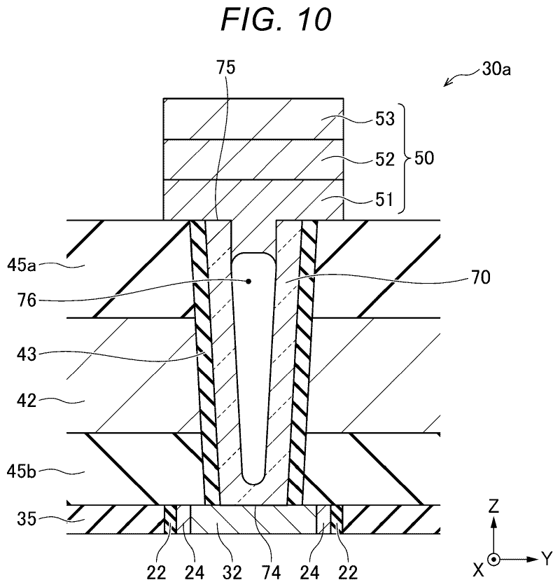

Next, as illustrated in FIG. 9, the metal oxide layer 51, the barrier metal layer 52, and the metal film 53 are formed in this order on the upper surface of the formed body 30a. The opening portion of the long hole 76a formed in the oxide semiconductor layer 70 is closed by the metal oxide layer 51, whereby the cavity 76 is formed in the oxide semiconductor layer 70. Next, film formation, resist application, exposure, development, peeling, and the like are performed on the surfaces of the formed body 30a by a lithography method to form a mask, and then etching is performed to form the upper electrode 50 as illustrated in FIG. 10.

Next, in order to activate the oxide semiconductor layer 70 in the formed body 30a illustrated in FIG. 10, for example, oxygen annealing by heating is performed to supply oxygen to the oxide semiconductor layer 70. As a result, the oxygen is supplied from the sidewall of the metal oxide layer 51 to the oxide semiconductor layer 70 through the subjected metal oxide layer 51. At this time, the oxygen is supplied to the lower portion 72 of the oxide semiconductor layer 70 through the cavity 76 formed in the oxide semiconductor layer 70, so that the oxygen can be easily supplied to the entirety of the oxide semiconductor layer 70.

Subsequently, a process of forming an insulation layer 63 and the like are performed on the formed body 30a illustrated in FIG. 10, whereby the semiconductor device 30 illustrated in FIG. 3 is made.

### 1.4 Effects

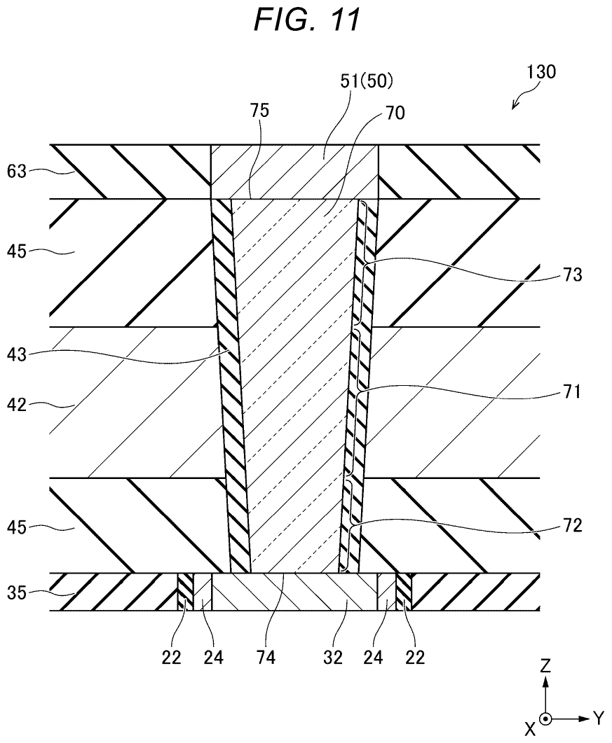

FIG. 11 is a cross-sectional view illustrating a cross-sectional structure of a semiconductor device 130 of a comparative example. The semiconductor device 130 has the same structure as the semiconductor device 30 illustrated in FIG. 3, except that the cavity 76 is not provided. In the semiconductor device 130 illustrated in FIG. 10, the same elements as those in the semiconductor device 30 illustrated in FIG. 3 are denoted by the same reference signs.

In the semiconductor device 130 illustrated in FIG. 11, a threshold voltage Vth of the semiconductor device 130 can be shifted to the positive side by thinning the oxide semiconductor layer 70 functioning as a channel in a direction perpendicular to the Z-axis direction. However, when the oxide semiconductor layer 70 is thinned in the direction perpendicular to the Z-axis direction, a contact area between the oxide semiconductor layer 70 and the lower electrode 32, and a contact area between the oxide semiconductor layer 70 and the upper electrode 50 are both reduced. As a result, the on-current of the semiconductor device 130 may be reduced.

In this regard, the semiconductor device 30 includes the oxide semiconductor layer 70, the lower electrode 32, the upper electrode 50, and the conductive layer 42. The oxide semiconductor layer 70 is provided such that the oxide semiconductor layer 70 includes the lower end 74 and the upper end 75 and extends in the +Z direction from the lower end 74 toward the upper end 75. The lower electrode 32 is in contact with the lower end 74 of the oxide semiconductor layer 70. The upper electrode 50 is in contact with the upper end 75 of the oxide semiconductor layer 70. The conductive layer 42 surrounds the intermediate portion 71 of the oxide semiconductor layer 70 via the gate insulation film 43. The cavity 76 is formed in the intermediate portion 71 of the oxide semiconductor layer 70.

When the cavity 76 is formed in the intermediate portion 71 of the oxide semiconductor layer 70 as in the above-described configuration, only the intermediate portion 71 near the conductive layer 42 functioning as a gate electrode of the field-effect transistor 40 can be thinned in the oxide semiconductor layer 70. As a result, the threshold voltage Vth of the semiconductor device 30 can be shifted to the positive side. In addition, an S value of the semiconductor device 30 can also be improved.

Further, when the cavity 76 is formed at the intermediate portion 71 of the oxide semiconductor layer 70 near the conductive layer 42, a contact area between the lower portion 72 of the oxide semiconductor layer 70 and the lower electrode 32 and a contact area between the upper portion 73 of the oxide semiconductor layer 70 and the upper electrode 50 can be maintained, and thus the on-current of the field-effect transistor 40 can also be maintained.

As illustrated in FIG. 3, even when the cavity 76 is formed at the intermediate portion 71 of the oxide semiconductor layer 70, it is possible to maintain a width from an interface BF with the gate insulation film 43 to an inner wall of the cavity 76 at a predetermined length H in the oxide semiconductor layer 70. According to experiments by the inventors, it was confirmed that, by setting the length H to 4 nm or greater, it is possible to secure a region in which the concentration of carriers becomes high in the oxide semiconductor layer 70 when the field-effect transistor 40 is turned on. In the semiconductor device 30 described above, a region in which the concentration of carriers becomes high in the oxide semiconductor layer 70 is secured by setting the length H to 4 nm or greater. With this configuration, the on-current of the field-effect transistor 40 can also be maintained.

### 1.5 First Modification Example of Semiconductor Device

Next, a first modification example of the semiconductor device 30 will be described.

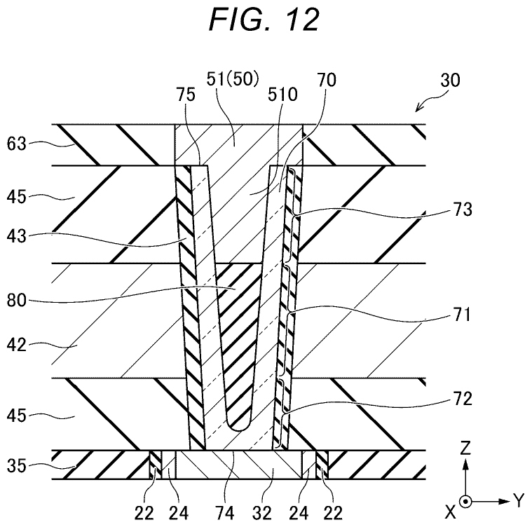

As illustrated in FIG. 12, in the semiconductor device 30 of the present modification example, an insulation layer 80 is embedded in the oxide semiconductor layer 70 instead of the cavity 76. The insulation layer 80 is made of either silicon oxide or alumina.

The semiconductor device 30 is manufactured as follows, for example. First, after the formed body 30a illustrated in FIG. 8 is made, the insulation layer 80 is formed on the upper surface of the formed body 30a. As a result, the insulation layer 80 is embedded in the long hole 76a. Subsequently, a part of the insulation layer 80 is selectively removed by etching using silicon nitride (SiN) or phosphoric acid, and then processes similar to the processes illustrated in FIG. 9 and FIG. 10 are performed.

### 1.6 Second Modification Example of Semiconductor Device

Next, a second modification example of the semiconductor device 30 will be described.

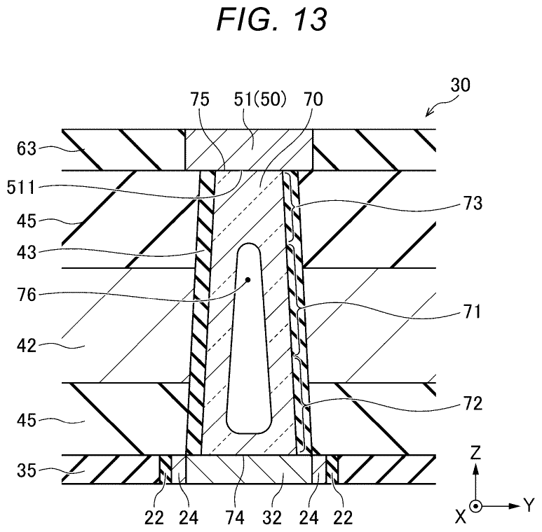

As illustrated in FIG. 13, in the semiconductor device 30 of the present modification example, the oxide semiconductor layer 70 and the gate insulation film 43 are inversely tapered to become narrower toward the +Z direction. Similarly, the cavity 76 is also inversely tapered to become narrower toward the +Z direction. In addition, the semiconductor device 30 of the present modification example differs from the above-described semiconductor device 30 in that the projecting portion 510 is not formed at the metal oxide layer 51. A bottom surface 511 of the metal oxide layer 51 is in contact with the upper portion 73 of the oxide semiconductor layer 70. Thus, the upper part of the cavity 76 is not in contact with the metal oxide layer 51.

The semiconductor device 30 is made as follows, for example. First, the transistor hole TH illustrated in FIG. 4 is formed in an inverse tapered shape, and then processes similar to the processes illustrated in FIG. 5 to FIG. 10 are performed. When the transistor hole TH is formed in an inverse tapered shape, the gate insulation film 43 is also formed in an inverse tapered shape by performing processes similar to the processes illustrated in FIG. 5 and FIG. 6 to form the gate insulation film 43 on the transistor hole TH. Then, the oxide semiconductor layer 70 is formed by an atomic layer deposition method by performing processes similar to the processes illustrated in FIG. 7 and FIG. 8, whereby the long hole 76a illustrated in FIG. 8 is also formed in an inverse tapered shape. Consequently, the cavity 76 having an inverse tapered shape can be easily formed.

### 1.7 Third Modification Example of Semiconductor Device

Next, a third modification example of the semiconductor device 30 will be described.

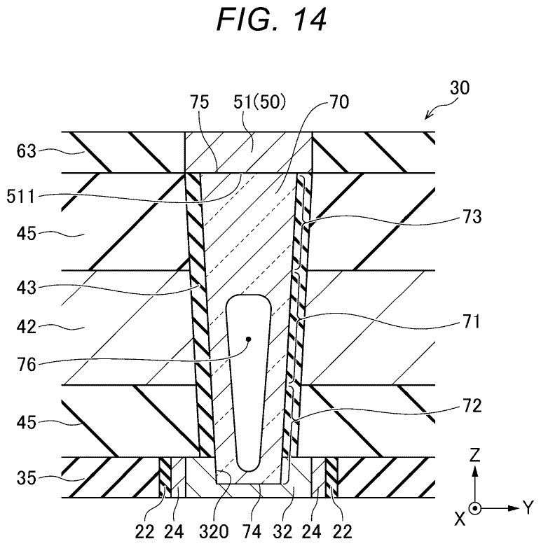

As illustrated in FIG. 14, the semiconductor device 30 of the present modification example differs from the above-described semiconductor device 30 in that the projecting portion 510 is not formed at the metal oxide layer 51. The bottom surface 511 of the metal oxide layer 51 is in contact with the upper portion 73 of the oxide semiconductor layer 70. Thus, the upper part of the cavity 76 is not in contact with the metal oxide layer 51. In the semiconductor device 30 of the present modification example, a recess 320 is formed in the lower electrode 32, and the lower portion 72 of the oxide semiconductor layer 70 extends to the inside of the recess 320. The lower part of the cavity 76 is formed to extend in the lower portion 72 of the oxide semiconductor layer 70 and is located in the recess 320. Thus, the cavity 76 extends from the intermediate portion 71 of the oxide semiconductor layer 70 to the inside of the recess 320.

### 1.8 Fourth Modification Example of Semiconductor Device

Next, a fourth modification example of the semiconductor device 30 will be described.

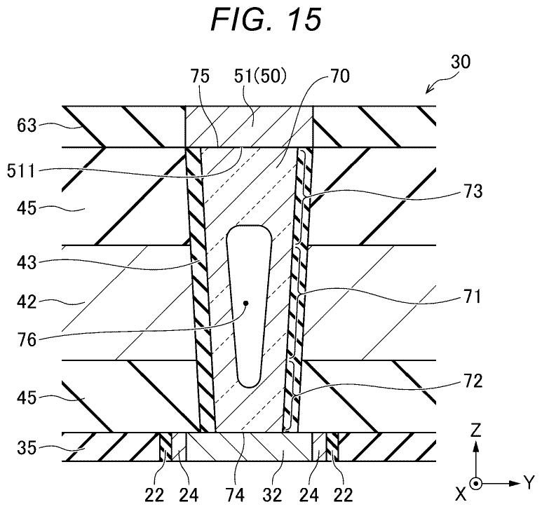

As illustrated in FIG. 15, the semiconductor device 30 of the present modification example differs from the above-described semiconductor device 30 illustrated in FIG. 3 in that the projecting portion 510 is not formed at the metal oxide layer 51. The bottom surface 511 of the metal oxide layer 51 is in contact with the upper portion 73 of the oxide semiconductor layer 70. Thus, the upper part of the cavity 76 is not in contact with the metal oxide layer 51.

### 1.9 Fifth Modification Example of Semiconductor Device

Next, a fifth modification example of the semiconductor device 30 will be described.

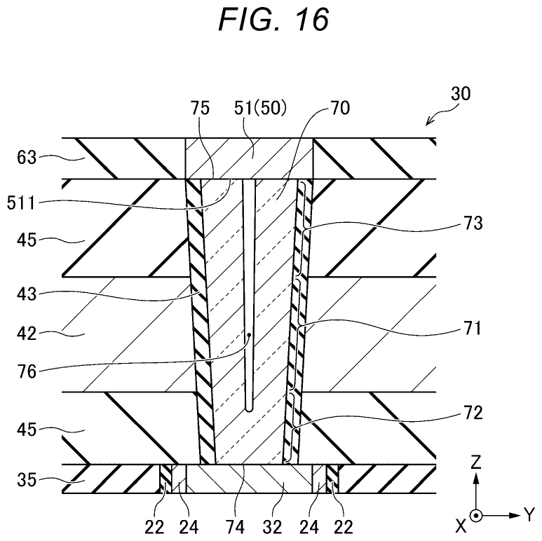

As illustrated in FIG. 16, the semiconductor device 30 of the present modification example differs from the above-described semiconductor device 30 illustrated in FIG. 3 in that the projecting portion 510 is not formed at the metal oxide layer 51. The bottom surface 511 of the metal oxide layer 51 is in contact with the upper part of the cavity 76.

### 1.10 Sixth Modification Example of Semiconductor Device

Next, a sixth modification example of the semiconductor device 30 will be described.

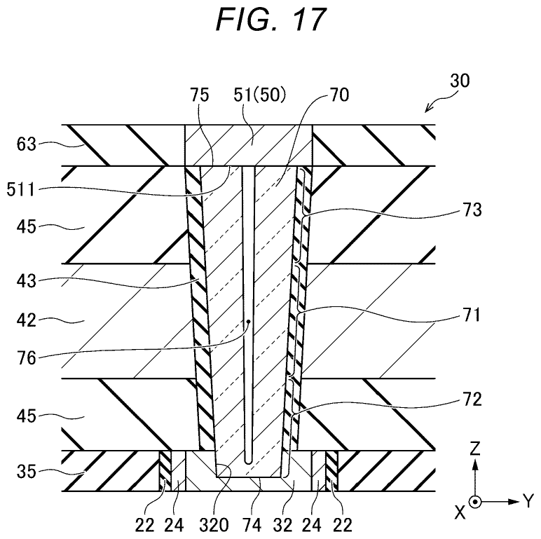

As illustrated in FIG. 17, the semiconductor device 30 of the present modification example differs from the above-described semiconductor device 30 in that the projecting portion 510 is not formed at the metal oxide layer 51. The bottom surface 511 of the metal oxide layer 51 is in contact with the upper part of the cavity 76. In the semiconductor device 30 of the present modification example, the recess 320 is formed in the lower electrode 32, and the lower portion 72 of the oxide semiconductor layer 70 extends to the inside of the recess 320. The cavity 76 extends from the intermediate portion 71 of the oxide semiconductor layer 70 to the inside of the recess 320.

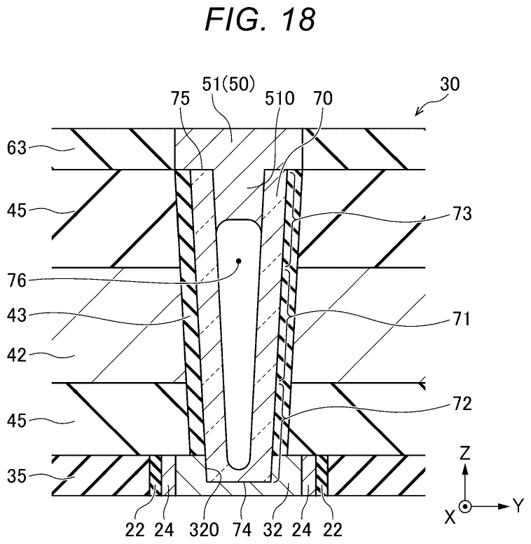

In the semiconductor device 30 of the present modification example, the projecting portion 510 may be formed at the metal oxide layer 51 as illustrated in FIG. 18, and the upper part of the cavity 76 may be in contact with the projecting portion 510, for example.

### 1.11 Seventh Modification Example of Semiconductor Device

Next, a seventh modification example of the semiconductor device 30 will be described.

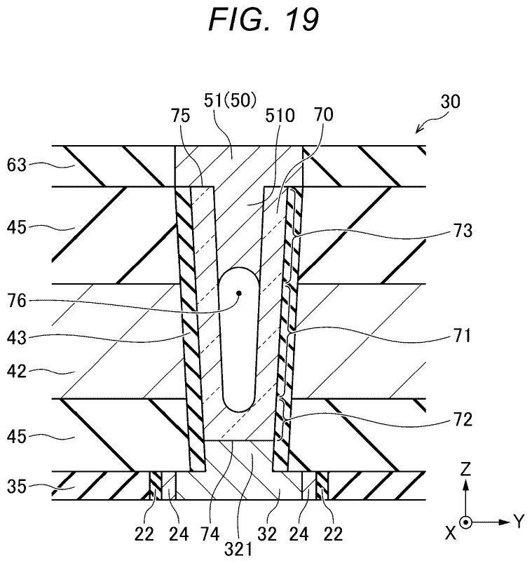

In the semiconductor device 30 of the present modification example, the lower electrode 32 is formed with a projecting portion 321 as illustrated in FIG. 19. The projecting portion 321 projects to the inside of the lower portion of the gate insulation film 43.

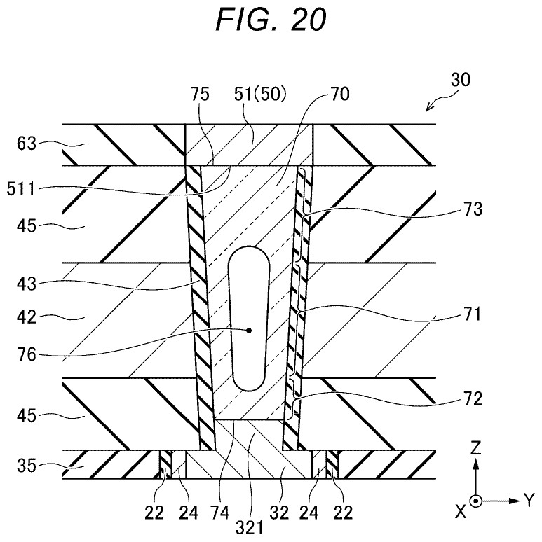

It should be noted that, in the semiconductor device 30 of the present modification example, when a structure similar to the structure illustrated in FIG. 15 is employed, the upper part of the cavity 76 is not necessarily in contact with the metal oxide layer 51 as illustrated in FIG. 20, for example.

### 1.12 Eighth Modification Example of Semiconductor Device

Next, an eighth modification example of the semiconductor device 30 will be described.

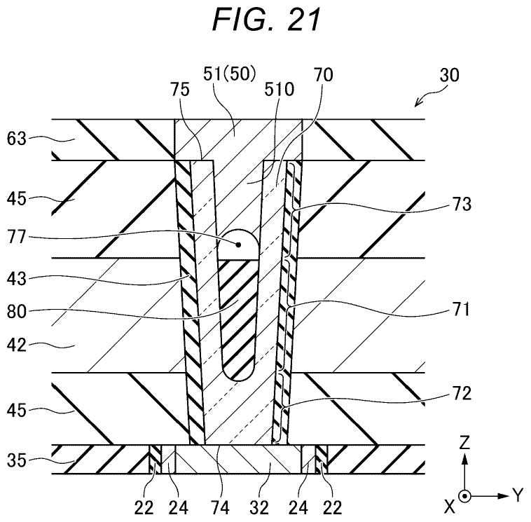

As illustrated in FIG. 21, the semiconductor device 30 of the present modification example differs from the semiconductor device 30 illustrated in FIG. 12 in that a cavity 77 is formed between the projecting portion 510 of the metal oxide layer 51 and the insulation layer 80. In the semiconductor device 30 of the present modification example, the insulation layer 80 is provided in the intermediate portion 71 of the oxide semiconductor layer 70 as illustrated in FIG. 21. Further, the cavity 77 is formed in the oxide semiconductor layer 70 so as to be adjacent to the insulation layer 80 in the +Z direction. In this manner, both the insulation layer 80 and the cavity 77 are formed in the oxide semiconductor layer 70.

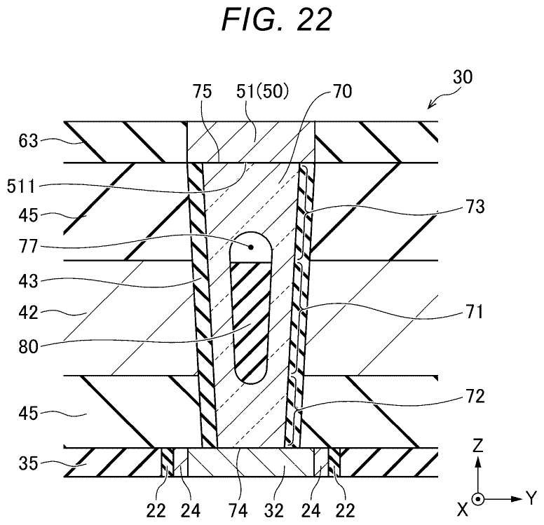

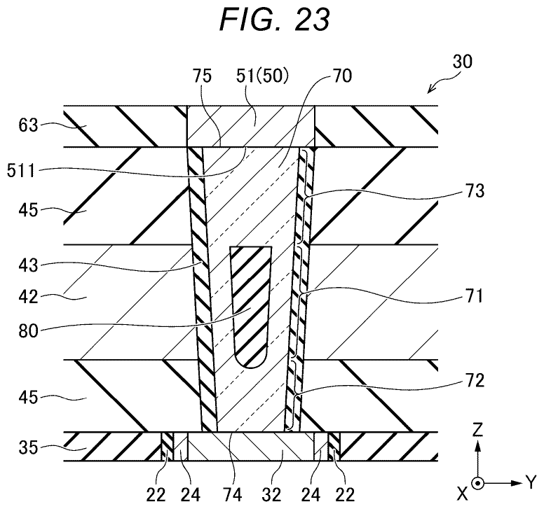

It should be noted that the projecting portion 510 may be eliminated from the metal oxide layer 51, and the upper portion 73 of the oxide semiconductor layer 70 may be in contact with the bottom surface 511 of the metal oxide layer 51 as illustrated in FIG. 22. In addition, for the semiconductor device 30 illustrated in FIG. 22, the cavity 77 may be eliminated as illustrated in FIG. 23.

### Other Embodiments

The present disclosure is not limited to the specific examples described above.

For example, as a method for supplying oxygen to the oxide semiconductor layer 70 in the manufacturing process of the semiconductor device 30, oxygen may be supplied to the oxide semiconductor layer 70 by performing a process illustrated in FIG. 7, that is, a process of forming the oxide semiconductor layer 70 in an oxygen atmosphere.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
an oxide semiconductor layer extending in a first direction and including a first end portion, a second end portion, and an intermediate portion between the first and second end portions;
a first electrode in contact with the first end portion of the oxide semiconductor layer;
a second electrode in contact with the second end portion of the oxide semiconductor layer; and
a conductive layer surrounding the intermediate portion of the oxide semiconductor layer via an insulation film, wherein
at least one of a cavity or an insulation layer is disposed in the intermediate portion of the oxide semiconductor layer.

2. The semiconductor device according to claim 1, wherein the first electrode does not face at least one of the cavity or the insulation layer in a second direction that is perpendicular to the first direction.

3. The semiconductor device according to claim 1, wherein the first electrode has a recess in which the first end portion of the oxide semiconductor layer is embedded.

4. The semiconductor device according to claim 3, wherein at least one of the cavity or the insulation layer extends from the intermediate portion of the oxide semiconductor layer to the first end portion of the oxide semiconductor layer that is embedded in the recess.

5. The semiconductor device according to claim 1, wherein the second electrode does not face at least one of the cavity or the insulation layer in a second direction that is perpendicular to the first direction.

6. The semiconductor device according to claim 1, wherein the second electrode includes a projecting portion surrounded by the oxide semiconductor layer.

7. The semiconductor device according to claim 6, wherein a leading end portion of the projecting portion faces at least one of the cavity or the insulation layer in the first direction.

8. The semiconductor device according to claim 1, wherein the oxide semiconductor layer is tapered in the first direction.

9. The semiconductor device according to claim 8, wherein at least one of the cavity or the insulation layer is tapered in the first direction.

10. The semiconductor device according to claim 1, wherein the insulation layer is provided in the intermediate portion of the oxide semiconductor layer.

11. The semiconductor device according to claim 10, wherein the cavity is further formed in the oxide semiconductor layer, the cavity being adjacent to the insulation layer in the first direction.

12. The semiconductor device according to claim 1, wherein the insulation layer is made of silicon oxide or alumina.

13. The semiconductor device according to claim 1, wherein the cavity extends from the first end portion of the oxide semiconductor layer to the second end portion of the oxide semiconductor layer.

14. A semiconductor memory device comprising:
a substrate;
an oxide semiconductor layer above the substrate and extending in a first direction that is perpendicular to the substrate, the oxide semiconductor layer including a first end portion, a second end portion, and an intermediate portion between the first and second end portions;
a first electrode between the substrate and the oxide semiconductor layer and in contact with the first end portion of the oxide semiconductor layer;
a second electrode in contact with the second end portion of the oxide semiconductor layer; and
a conductive layer surrounding the intermediate portion of the oxide semiconductor layer via an insulation film, wherein
at least one of a cavity or an insulation layer is disposed in the intermediate portion of the oxide semiconductor layer.

15. The semiconductor memory device according to claim 14, wherein the first electrode has a recess in which the first end portion of the oxide semiconductor layer is embedded.

16. The semiconductor memory device according to claim 14, wherein the second electrode includes a projecting portion surrounded by the oxide semiconductor layer.

17. The semiconductor memory device according to claim 16, wherein a leading end portion of the projecting portion faces at least one of the cavity or the insulation layer in the first direction.

18. The semiconductor memory device according to claim 14, wherein the oxide semiconductor layer is tapered in the first direction.

19. A method for manufacturing a semiconductor device, the method comprising:
stacking a first conductive layer, a first insulation layer, a conductive layer, and a second insulation layer in a first direction;
making a hole penetrating the second insulation layer, the conductive layer, and the first insulation layer and reaching the first conductive layer;
forming an oxide semiconductor layer in the hole by an atomic layer deposition (ALD) method such that a cavity is formed in a portion of the oxide semiconductor layer surrounded by the conductive layer; and
supplying oxygen to the oxide semiconductor layer.

20. The method according to claim 19, further comprising:
forming a third insulation layer in the cavity.
